(19) United States
(12) Patent Application Publication
(10) Pub. No.: US 2018/0233485 A1
(43) Pub. Date: Aug. 16, 2018

(54) SEMICONDUCTOR STRUCTURE AND MANUFACTURING METHOD THEREOF

(71) Applicant: NANYA TECHNOLOGY CORPORATION, Taoyuan City (TW)

(72) Inventors: Po-Chun LIN, CHANGHUA CITY (TW); Chin-Lung CHU, TAOYUAN CITY (TW)

(21) Appl. No.: 15/432,554

(22) Filed: Feb. 14, 2017

(51) Int. Cl. H01L 25/065; H01L 23/48; H01L 23/498; H01L 23/00; H01L 25/00; H01L 21/48

(52) U.S. Cl. CPC H01L 25/0657; H01L 2224/13139; H01L 23/49811; H01L 23/49866; H01L 24/32; H01L 24/16; H01L 25/50; H01L 21/4853; H01L 2225/06517; H01L 2225/06541; H01L 2225/06548; H01L 2225/06565; H01L 2924/01029; H01L 2924/01047; H01L 2924/01079; H01L 2924/0105; H01L 2224/32225; H01L 2224/16227; H01L 2224/16145; H01L 2225/06513; H01L 2224/13147; H01L 2224/13155; H01L 2224/13144; H01L 23/481

(57) ABSTRACT

A semiconductor structure includes a substrate including a conductive pillar protruded from the substrate; and a first chip disposed over the substrate and including a first via extended through the first chip, wherein the conductive pillar is extended from the substrate through the first chip and is partially disposed within the first via.

### TECHNICAL FIELD

The present disclosure relates to a semiconductor structure, and particularly relates to several chips stacked over each other and a conductive pillar extending through the chips and electrically connecting the chips. Further, the present disclosure relates to a method of manufacturing the semiconductor structure comprising the stacked chips and the conductive pillar extending through the chips.

### DISCUSSION OF THE BACKGROUND

Semiconductor devices are essential for many modern applications. With the advancement of electronic technology, semiconductor devices are becoming smaller in size while providing greater functionality and comprising greater amounts of integrated circuitry. Due to the miniaturized scale of semiconductor devices, various types and dimensions of semiconductor devices performing different functions are integrated and packaged into a single module. Furthermore, numerous manufacturing operations are implemented for integration of various types of semiconductor devices.

However, the manufacturing and integration of semiconductor devices involve many complicated steps and operations. Integration of a semiconductor device having a low profile and high density becomes increasingly complicated. An increase in complexity of manufacturing and integration of the semiconductor device may cause deficiencies such as poor electrical interconnection, misalignment of dies or components, delamination of components, or high yield loss. Accordingly, there is a continuous need to improve the structure and the manufacturing process of semiconductor devices.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure comprising a substrate including a conductive pillar protruded from the substrate; and a first chip disposed over the substrate and including a first via extended through the first chip, wherein the conductive pillar is extended from the substrate through the first chip and is partially disposed within the first via.

In some embodiments, the substrate is vertically aligned with the first chip by the conductive pillar.

In some embodiments, the semiconductor structure further includes a first intermediate member disposed within the first via and surrounding a portion of the conductive pillar.

In some embodiments, a melting point of the conductive pillar is substantially higher than a melting point of the first intermediate member.

In some embodiments, the first intermediate member includes tin or solder.

In some embodiments, the conductive pillar is disposed over or partially protruded into the substrate.

In some embodiments, the substrate includes a conductive pad disposed over a surface of the substrate or disposed within the substrate, and the conductive pillar is electrically coupled with the conductive pad.

In some embodiments, the conductive pillar includes copper, silver or gold.

In some embodiments, the semiconductor structure further includes a second chip disposed over the first chip and the substrate and including a second via extended through the second chip, wherein the conductive pillar is extended through the second chip and is partially disposed within the second via.

In some embodiments, the conductive pillar is partially protruded from the second chip.

In some embodiments, the second chip includes a second intermediate member disposed within the second via and surrounding a portion of the conductive pillar.

In some embodiments, the semiconductor structure further includes an adhesive disposed between the substrate and the first chip.

In some embodiments, the semiconductor structure further includes a first conductive bump disposed between the substrate and the first chip and electrically connecting the substrate with the first chip.

In some embodiments, the semiconductor structure further includes a second conductive bump disposed between the first chip and the second chip and electrically connecting the first chip with the second chip.

Another aspect of the present disclosure provides a method of manufacturing a semiconductor structure comprising providing a substrate; forming a conductive pillar disposed over and protruded from the substrate; providing a first chip including a first via extended through the first chip; and disposing the first chip over the substrate to insert the conductive pillar through the first via.

In some embodiments, the first chip includes a first intermediate member disposed within the first via, and the conductive pillar is inserted into the first intermediate member during the disposing of the first chip.

In some embodiments, the first intermediate member is deformable and penetrable by the conductive pillar during the disposing of the first chip.

In some embodiments, the forming of the conductive pillar includes disposing a photoresist over the substrate, removing a portion of the photoresist to form a recess, disposing a conductive material into the recess, and removing the photoresist from the substrate.

In some embodiments, the conductive material is disposed by electroplating, or the portion of the photoresist is removed by etching.

In some embodiments, the method further includes providing a second chip including a second via extended through the second chip; disposing the second chip over the first chip to insert the conductive pillar through the second via; providing the second chip including a second intermediate member disposed within the second via; and inserting the conductive pillar into the second intermediate member.

The present disclosure is directed to a semiconductor structure comprising several chips stacked over each other and a conductive pillar extended through the chips. As such, the chips are vertically aligned with each other. Misalignment of the chips can be minimized or prevented. Further, the conductive pillar can absorb or relieve stress that develops around a connector disposed between the chips. An internal stress of the semiconductor structure can thereby be reduced, minimized or prevented.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a semiconductor structure in accordance with some embodiments of the present disclosure.

FIG. 2 is a schematic cross-sectional view of a semiconductor structure in accordance with some embodiments of the present disclosure.

FIG. 3 is a schematic cross-sectional view of a semiconductor structure in accordance with some embodiments of the present disclosure.

FIG. 4 is a schematic cross-sectional view of a semiconductor structure in accordance with some embodiments of the present disclosure.

FIG. 5 is a flow chart of a method of manufacturing a semiconductor structure in accordance with some embodiments of the present disclosure.

FIGS. 6 to 24 are schematic views illustrating a process of manufacturing the semiconductor structure by the method of FIG. 5 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor structure comprising several chips stacked over each other and a conductive pillar extending through the chips. As such, the chips can align with each other by the conductive pillar. Misalignment of the chips can be minimized or prevented. Further, the conductive pillar can absorb or relieve stress that develops around a connector disposed between the chips. Thus, internal stress of the semiconductor structure can be minimized or prevented. The present disclosure is also directed to a method of manufacturing a semiconductor structure comprising forming a conductive pillar over a substrate and disposing several chips over the substrate. The conductive pillar extends through the chips, such that the chips are aligned with each other by the conductive pillar. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

An electronic device including various semiconductor devices is manufactured by a number of operations. During the manufacturing process, the semiconductor devices with different functionalities and dimensions are integrated into a single module. Chips are stacked over each other, and circuitries of the chips are integrated and connected through conductive traces and connectors. However, the chips may not be accurately disposed over each other due to misalignment, which is undesirable.

In the present disclosure, a semiconductor structure is disclosed. The semiconductor structure comprises a substrate including a conductive pillar protruding from the substrate, and a chip disposed over the substrate and including a via (conductive plug) extending through the chip. The conductive pillar extends from the substrate through the chip and is partially disposed within the via. Accordingly, the chip can be accurately disposed. The chip is aligned with the substrate by the conductive pillar. As a result, misalignment of the chip can be minimized or prevented. Further, the conductive pillar can absorb or relieve stress that develops around a connector disposed between the chip and the substrate.

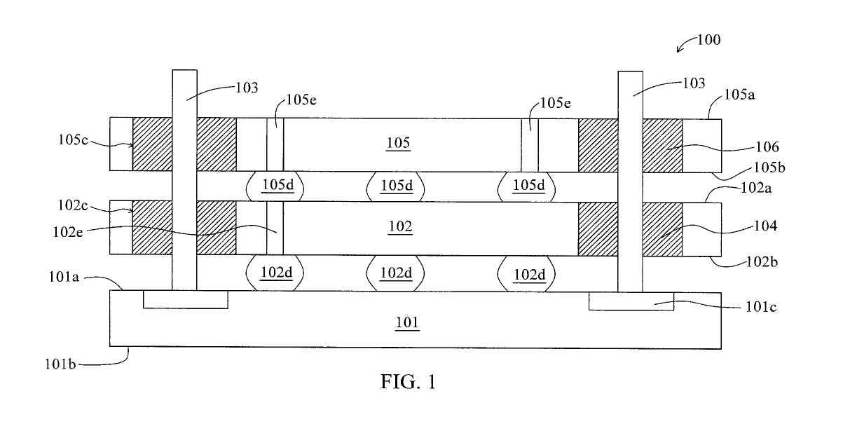

FIG. 1 is a cross-sectional view of a semiconductor structure 100 in accordance with some embodiments of the present disclosure. In some embodiments, the semiconductor structure 100 includes a substrate 101, a first chip 102 and a conductive pillar 103.

In some embodiments, the semiconductor structure 100 is a part of a semiconductor package or a semiconductor device. In some embodiments, the semiconductor structure 100 is a semiconductor package or a semiconductor device. In some embodiments, the semiconductor structure 100 is a part of a wafer level multiple chip package (WLMCP). In some embodiments, the semiconductor structure 100 is a WLMCP.

In some embodiments, the substrate 101 is a semiconductive substrate. In some embodiments, the substrate 101 is a wafer or a carrier. In some embodiments, the substrate 101 is a capping substrate or a capping carrier. In some embodiments, the substrate 101 includes semiconductive material such as silicon, germanium, gallium, arsenic, or combinations thereof. In some embodiments, the substrate 101 is a silicon substrate. In some embodiments, the substrate 101 includes material such as ceramic, glass or the like. In some embodiments, the substrate 101 includes organic material. In some embodiments, the substrate 101 is a glass substrate. In some embodiments, the substrate 101 is a packaging substrate. In some embodiments, the substrate 101 has a quadrilateral, rectangular, square, polygonal or any other suitable shape.

In some embodiments, the substrate 101 is fabricated with a predetermined functional circuit thereon. In some embodiments, the substrate 101 includes several conductive traces and several electrical components such as transistor, diode, etc. disposed within the substrate 101.

In some embodiments, the substrate 101 includes a first surface 101a and a second surface 101b opposite to the first surface 101a. In some embodiments, the first surface 101a is a front side or an active side on which the circuits or electrical components are disposed. In some embodiments, a device is disposed over the first surface 101a of the substrate 101. In some embodiments, the second surface 101b is a back side or an inactive side. In some embodiments, no device or electrical component is disposed over the second surface 101b.

In some embodiments, a conductive pad 101c is disposed over the substrate 101. In some embodiments, the conductive pad 101c is disposed over the first surface 101a of the substrate 101. In some embodiments, the conductive pad 101c is electrically connected to circuitry inside the substrate 101. In some embodiments, the conductive pad 101c is configured to receive a conductive structure. In some embodiments, the conductive pad 101c is a bond pad. In some embodiments, the conductive pad 101c includes gold, silver, copper, nickel, tungsten, aluminum, palladium or alloys thereof.

In some embodiments, the first chip 102 is a die, a chip or a package. In some embodiments, the first chip 102 is fabricated with a predetermined functional circuit within the first chip 102 produced by photolithography operations. In some embodiments, the first chip 102 is singulated from a semiconductive wafer by a mechanical blade or a laser blade. In some embodiments, the first chip 102 comprises a variety of electrical circuits suitable for a particular application. In some embodiments, the electrical circuits include various devices such as transistors, capacitors, resistors, diodes or the like.

In some embodiments, the first chip 102 comprises any of various known types of semiconductor devices such as accelerated processing unit (APU), memories, dynamic random access memory (DRAM), NAND flash memory, central processing unit (CPU), graphic processing unit (GPU), microprocessors, application-specific integrated circuits (ASICs), digital signal processors (DSPs), or the like. In some embodiments, the first chip 102 is a logic device die or the like.

In some embodiments, the first chip 102 has a quadrilateral, rectangular, square, polygonal or any other suitable shape. In some embodiments, the first chip 102 is disposed over the substrate 101. In some embodiments, the first chip 102 is disposed over the first surface 101a of the substrate 101. In some embodiments, a dimension of the substrate 101 is substantially greater than, less than or equal to a dimension of the first chip 102.

In some embodiments, the first chip 102 includes a third surface 102a and a fourth surface 102b opposite to the third surface 102a. In some embodiments, the third surface 102a is a front side or an active side on which the circuits or electrical components are disposed. In some embodiments, the fourth surface 102b is a back side or an inactive side from which the circuits or electrical components are absent.

In some embodiments, the first chip 102 includes a first via 102c extending through the first chip 102. In some embodiments, the first via 102c extends between the third surface 102a and the fourth surface 102b of the first chip 102.

In some embodiments, a first conductive bump 102d is disposed between the substrate 101 and the first chip 102. In some embodiments, the first conductive bump 102d is disposed between the first surface 101a of the substrate 101 and the fourth surface 102b of the first chip 102. In some embodiments, the first conductive bump 102d electrically connects the substrate 101 with the first chip 102. In some embodiments, the first conductive bump 102d includes conductive material such as solder, copper, nickel, or gold. In some embodiments, the first conductive bump 102d is a solder ball, a ball grid array (BGA) ball, a controlled collapse chip connection (C4) bump, a microbump, a pillar or the like. In some embodiments, the first conductive bump 102d has a spherical, hemispherical or cylindrical shape.

In some embodiments, a first conductive post 102e extends through the first chip 102. In some embodiments, the first conductive post 102e extends between the third surface 102a and the fourth surface 102b of the first chip 102. In some embodiments, the first conductive post 102e is electrically connected with the first conductive bump 102d. In some embodiments, the first conductive post 102e includes conductive material such as copper, silver, gold, etc.

In some embodiments, the conductive pillar 103 is disposed over the substrate 101. In some embodiments, the conductive pillar 103 protrudes from the substrate 101. In some embodiments, the conductive pillar 103 protrudes from the first surface 101a of the substrate 101. In some embodiments, the conductive pillar 103 extends from the substrate 101 through the first chip 102 and is partially disposed within the first via 102c. In some embodiments, a portion of the conductive pillar 103 protrudes from the first chip 102. In some embodiments, the conductive pillar 103 protrudes from the conductive pad 101c of the substrate 101. In some embodiments, the conductive pillar 103 is electrically coupled with the conductive pad 101c. In some embodiments, the substrate 101 is vertically aligned with the first chip by the conductive pillar 103. In some embodiments, the conductive pillar 103 is of a cylindrical shape. In some embodiments, a cross section of the conductive pillar 103 is of a circular, rectangular, quadrilateral or polygonal shape.

In some embodiments, the conductive pillar 103 has a high melting point. In some embodiments, the melting point of the conductive pillar 103 is greater than about 800° C. In some embodiments, the conductive pillar 103 includes conductive material such as copper, silver, gold, etc.

In some embodiments, a first intermediate member 104 is disposed within the first via 102c and surrounds a portion of the conductive pillar 103. In some embodiments, the first intermediate member 104 is disposed between the conductive pillar 103 and the first chip 102. In some embodiments, the first intermediate member 104 is disposed between the third surface 102a and the fourth surface 102b of the first chip 102.

In some embodiments, the first intermediate member 104 has a low melting point. In some embodiments, the melting point of the first intermediate member 104 is less than about 250° C. In some embodiments, the first intermediate member 104 includes tin or solder. In some embodiments, the melting point of the conductive pillar 103 is substantially higher than the melting point of the first intermediate member 104.

In some embodiments, the semiconductor structure 100 includes a second chip 105 disposed or stacked over the first chip 102 and the substrate 101. In some embodiments, the second chip 105 has a configuration similar to that of the first chip 102. In some embodiments, the second chip 105 includes a fifth surface 105a and a sixth surface 105b opposite to the fifth surface 105a. In some embodiments, the fifth surface 105a has a configuration similar to that of the third surface 102a, and the sixth surface 105b has a configuration similar to that of the fourth surface 102b.

In some embodiments, the second chip 105 includes a second via 105c extending through the second chip 105. In some embodiments, the second via 105c extends between the fifth surface 105a and the sixth surface 105b of the second chip 105. In some embodiments, the conductive pillar 103 extends through the second chip 105 and is partially disposed within the second via 105c. In some embodiments, the conductive pillar 103 partially protrudes from the second chip 105. In some embodiments, the second via 105c has a configuration similar to that of the first via 102c.

In some embodiments, a second conductive bump 105d is disposed between the first chip 102 and the second chip 105. In some embodiments, the second conductive bump 105d is disposed between the third surface 102a of the first chip 102 and the sixth surface 105b of the second chip 105. In some embodiments, the second conductive bump 105d electrically connects the first chip 102 with the second chip 105. In some embodiments, the second conductive bump 105d has a configuration similar to that of the first conductive bump 102d.

In some embodiments, a second conductive post 105e extends through the second chip 105. In some embodiments, the second conductive post 105e extends between the fifth surface 105a and the sixth surface 105b of the second chip 105. In some embodiments, the second conductive post 105e is electrically connected with the second conductive bump 105d. In some embodiments, the second conductive post 105e has a configuration similar to that of the first conductive post 102e.

In some embodiments, a second intermediate member 106 is disposed within the second via 105c and surrounds a portion of the conductive pillar 103. In some embodiments, the second intermediate member 106 is disposed between the conductive pillar 103 and the second chip 105. In some embodiments, the second intermediate member 106 is disposed between the fifth surface 105a and the sixth surface 105b of the second chip 105. In some embodiments, the second intermediate member 106 has a configuration similar to that of the first intermediate member 104. In some embodiments, the melting point of the conductive pillar 103 is substantially higher than a melting point of the second intermediate member 106.

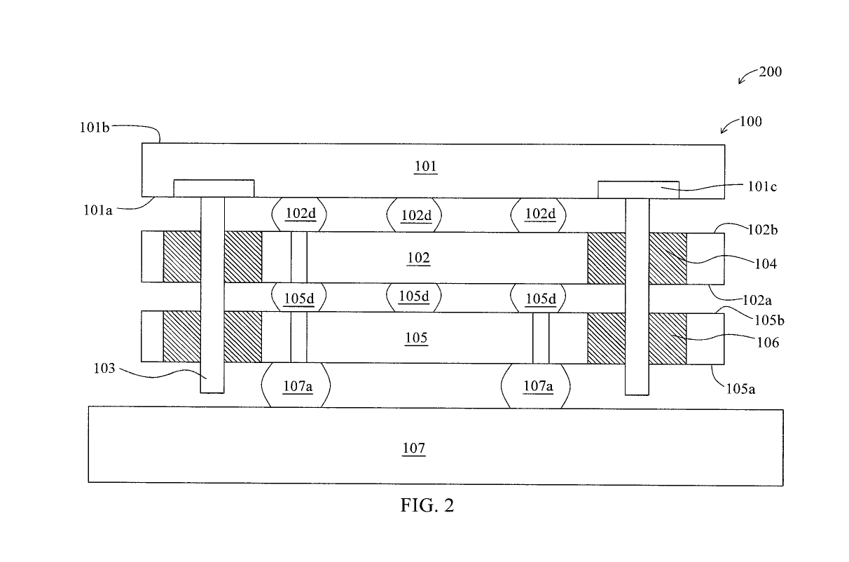

FIG. 2 is a cross-sectional view of a semiconductor structure 200 in accordance with some embodiments of the present disclosure. In some embodiments, the semiconductor structure 200 includes the semiconductor structure 100, with a configuration similar to those described above or illustrated in FIG. 1. In some embodiments, the semiconductor structure 100 is flipped and disposed over a circuit board 107.

In some embodiments, the circuit board 107 is a substrate, carrier or printed circuit board (PCB). In some embodiments, a connector 107a is disposed between the second chip 105 and the circuit board 107 and is electrically coupled with a component or circuitry of the circuit board 107, such that the first chip 102 and the second chip 105 are electrically connected to the circuit board 107. In some embodiments, the conductive pillar 103 is not electrically connected to the circuit board 107. In some embodiments, the conductive pillar 103 is disposed over and electrically connected to the circuit board 107.

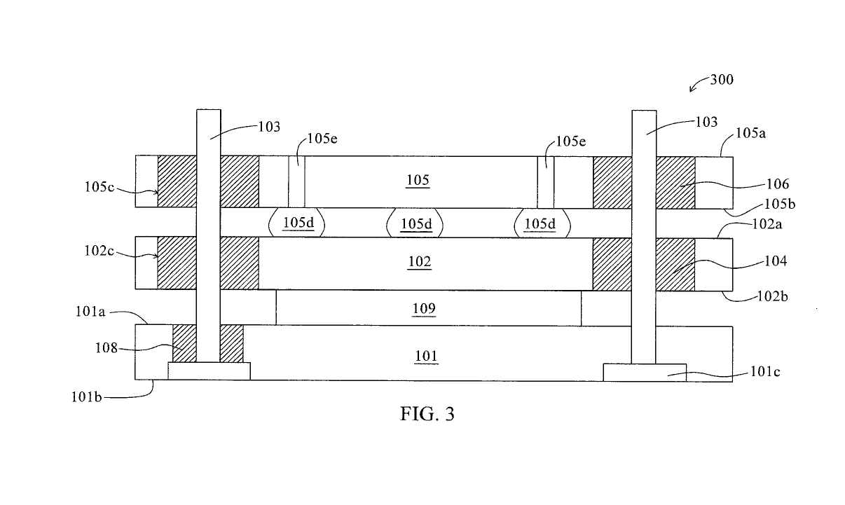

FIG. 3 is a cross-sectional view of a semiconductor structure 300 in accordance with some embodiments of the present disclosure. In some embodiments, the semiconductor structure 300 has a configuration similar to those described above or illustrated in FIG. 1 or 2.

In some embodiments, the conductive pad 101c of the substrate 101 is disposed within the substrate 101 or disposed over the second surface 101b of the substrate 101. In some embodiments, the conductive pillar 103 protrudes from the conductive pad 101c. In some embodiments, the conductive pillar 103 partially protrudes into the substrate 101.

In some embodiments, the substrate 101 includes a third intermediate member 108 disposed within the substrate 101 and surrounding a portion of the conductive pillar 103. In some embodiments, the third intermediate member 108 has a configuration similar to those of the first intermediate member 104 or the second intermediate member 106 described above or illustrated in FIG. 1 or 2. In some embodiments, a melting point of the third intermediate member 108 is substantially lower than the melting point of the conductive pillar 103.

In some embodiments, an adhesive 109 is disposed between the substrate 101 and the first chip 102. In some embodiments, the first chip 102 is attached to the substrate 101 by the adhesive 109. In some embodiments, the adhesive 109 is glue, die attach film (DAF), or the like.

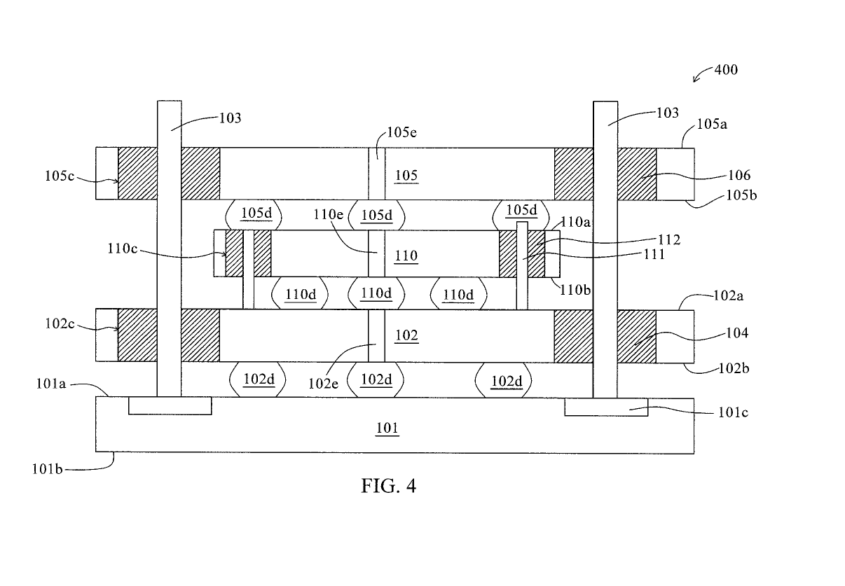

FIG. 4 is a cross-sectional view of a semiconductor structure 400 in accordance with some embodiments of the present disclosure. In some embodiments, the semiconductor structure 400 has a configuration similar to those described above or illustrated in FIG. 1 or 2.

In some embodiments, the semiconductor structure 400 includes a third chip 110 disposed between the first chip 102 and the second chip 105. In some embodiments, the third chip 110 has a configuration similar to those of the first chip 102 or the second chip 105. In some embodiments, the third chip 110 includes a seventh surface 110a and an eighth surface 110b opposite to the seventh surface 110a. In some embodiments, the seventh surface 110a has a configuration similar to those of the third surface 102a or the fifth surface 105a, and the eighth surface 110b has a configuration similar to those of the fourth surface 102b or the sixth surface 105b.

In some embodiments, the third chip 110 includes a third via 110c extending through the third chip 110. In some embodiments, the third via 110c extends between the seventh surface 110a and the eighth surface 110b. In some embodiments, a second conductive pillar 111 extends through the third chip 110 and is partially disposed within the third via 110c. In some embodiments, the second conductive pillar 111 partially protrudes from the third chip 110. In some embodiments, the second conductive pillar 111 is electrically connected to the second conductive bump 105d. In some embodiments, the second conductive pillar 111 is disposed over the first chip 102. In some embodiments, the second conductive pillar 111 protrudes from the first chip 102. In some embodiments, the second conductive pillar 111 protrudes into the second conductive bump 105d. In some embodiments, the third via 110c has a configuration similar to those of the first via 102c or the second via 105c. In some embodiments, the second conductive pillar 111 has a configuration similar to that of the conductive pillar 103.

In some embodiments, a third conductive bump 110d is disposed between the first chip 102 and the third chip 110. In some embodiments, the third conductive bump 110d is disposed between the third surface 102a of the first chip 102 and the eighth surface 110b of the third chip 110. In some embodiments, the third conductive bump 110d electrically connects the first chip 102 with the third chip 110. In some embodiments, the third conductive bump 110d has a configuration similar to those of the first conductive bump 102d or the second conductive bump 105d.

In some embodiments, a third conductive post 110e extends through the third chip 110. In some embodiments, the third conductive post 110e extends between the seventh surface 110a and the eighth surface 110b. In some embodiments, the third conductive post 110e is electrically connected with the second conductive bump 105d and the third conductive bump 110d. In some embodiments, the third conductive bump 110d is electrically connected to the first conductive bump 102d by the first conductive post 102e. In some embodiments, the third conductive post 110e has a configuration similar to those of the first conductive post 102e or the second conductive post 105e.

In some embodiments, a fourth intermediate member 112 is disposed within the third via 110c and surrounds a portion of the second conductive pillar 111. In some embodiments, the fourth intermediate member 112 is disposed between the second conductive pillar 111 and the third chip 110. In some embodiments, the fourth intermediate member 112 is disposed between the seventh surface 110a and the eighth surface 110b. In some embodiments, the fourth intermediate member 112 has a configuration similar to those of the first intermediate member 104 or the second intermediate member 106. In some embodiments, the melting point of the second conductive pillar 111 is substantially higher than a melting point of the fourth intermediate member 112.

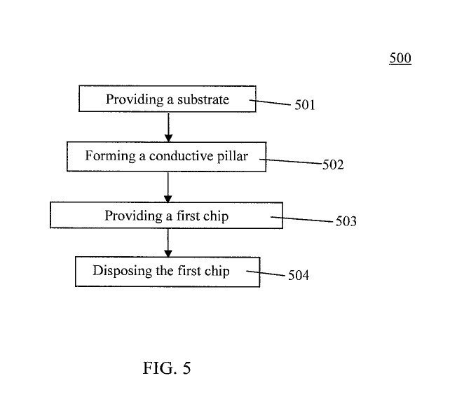

In the present disclosure, a method of manufacturing a semiconductor structure is also disclosed. In some embodiments, the semiconductor structure can be formed by a method 500 as shown in FIG. 5. The method 500 includes a number of operations and the description and illustration are not deemed as a limitation to the sequence of the operations. The method 500 includes a number of steps (501, 502, 503 and 504).

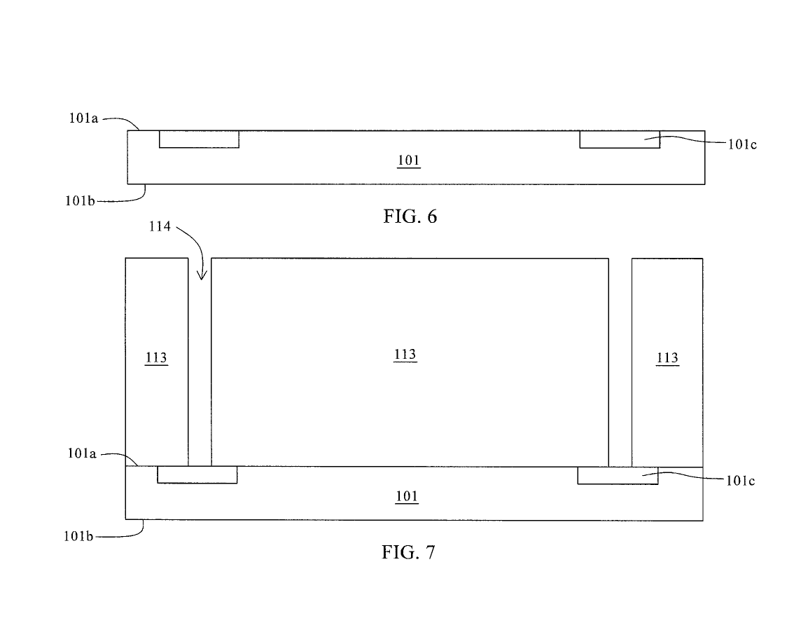

In step 501, a substrate 101 is provided or received as shown in FIG. 6. In some embodiments, the substrate 101 is a semiconductive substrate or wafer. In some embodiments, the substrate 101 is a carrier or a capping substrate. In some embodiments, the substrate 101 includes a conductive pad 101c disposed over the substrate 101. In some embodiments, the substrate 101 and the conductive pad 101c have configurations similar to those described above or illustrated in any of FIGS. 1 to 4.

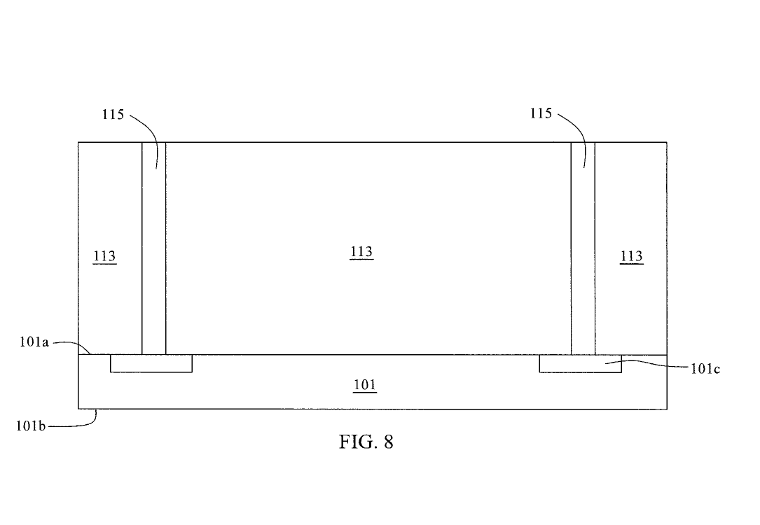

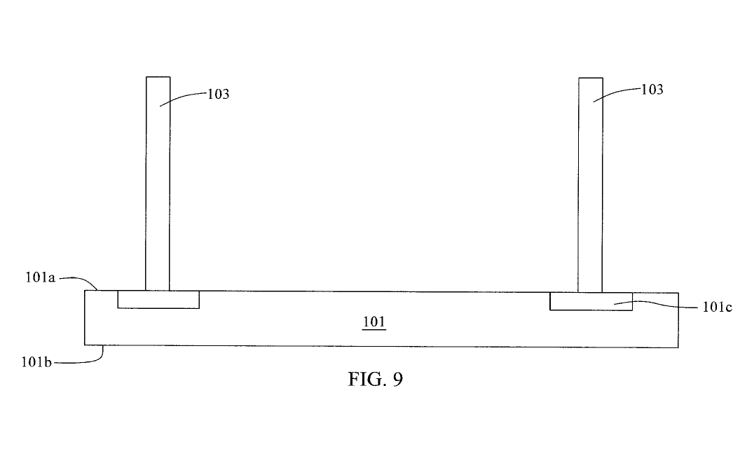

In step 502, a conductive pillar 103 is formed over the substrate 101 as shown in FIGS. 7 to 9. In some embodiments, the conductive pillar 103 protrudes from the substrate 101. In some embodiments, the conductive pillar 103 is formed over the conductive pad 101c. In some embodiments, the conductive pillar 103 is formed by disposing a photoresist 113 over the substrate 101, removing a portion of the photoresist 113 disposed over the conductive pad 101c to form a recess 114, disposing a conductive material 115 into the recess 114, and removing the photoresist 113 from the substrate 101. In some embodiments, the photoresist 113 is disposed by spin coating or any other suitable process. In some embodiments, the portion of the photoresist 113 is removed by etching or any other suitable process. In some embodiments, the conductive material 115 is disposed into the recess 114 by electroplating, sputtering or any other suitable process. In some embodiments, the photoresist 113 is removed by etching, stripping or any other suitable process. In some embodiments, the conductive pillar 103 has a configuration similar to those described above or illustrated in any of FIGS. 1 to 4.

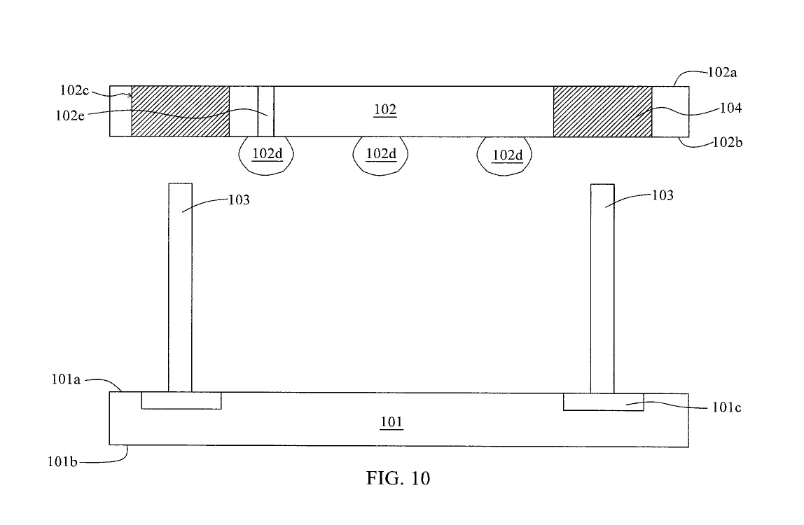

In step 503, a first chip 102 is provided or received as shown in FIG. 10. In some embodiments, the first chip 102 includes a first via 102c extending through the first chip 102. In some embodiments, a first intermediate member 104 is disposed within the first via 102c. In some embodiments, a first conductive bump 102d is disposed over a fourth surface 102b. In some embodiments, the first chip 102, the first via 102c, and the first conductive bump 102d have configurations similar to those described above or illustrated in any of FIGS. 1 to 4.

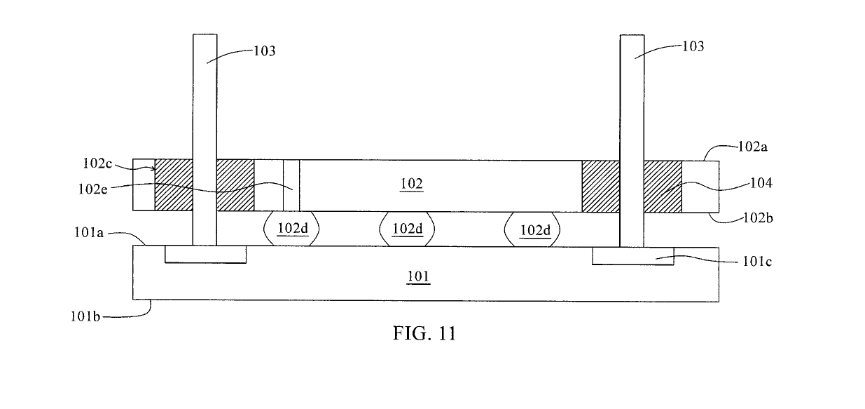

In step 504, the first chip 102 is disposed over the substrate 101 as shown in FIG. 11. In some embodiments, the conductive pillar 103 is inserted through the first via 102c. In some embodiments, the first intermediate member 104 is deformable and penetrable by the conductive pillar 103 during the disposing of the first chip 102. In some embodiments, the conductive pillar 103 is inserted into the first intermediate member 104 while the first intermediate member 104 is soft and has not been cured. In some embodiments, the first intermediate member 104 is cured after the disposing of the first chip 102. In some embodiments, the first conductive bump 102d is disposed over the substrate 101.

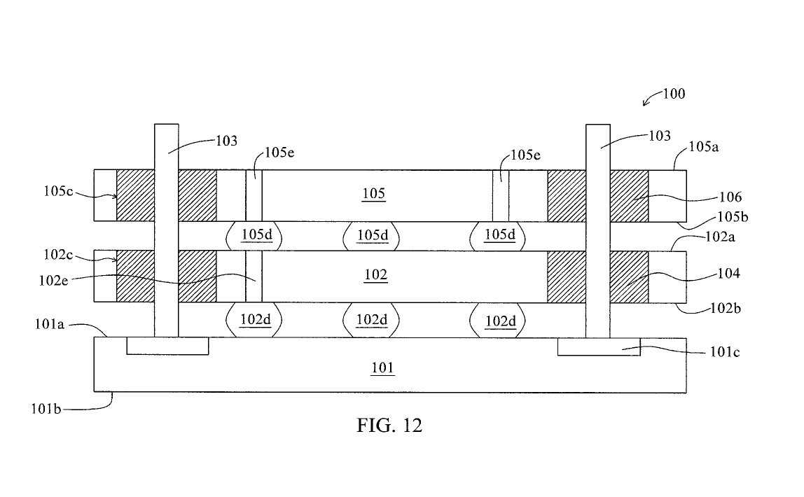

In some embodiments, a second chip 105 is disposed over the first chip 102 as shown in FIG. 12. In some embodiments, the second chip 105 includes a second via 105c extending through the second chip 105. In some embodiments, a second intermediate member 106 is disposed within the second via 105c. In some embodiments, a second conductive bump 105d is disposed over a sixth surface 105b. In some embodiments, the second chip 105, the second via 105c, and the second conductive bump 105d have configurations similar to those described above or illustrated in any of FIGS. 1 to 4.

In some embodiments, the second chip 105 is disposed over the first chip 102. In some embodiments, the conductive pillar 103 is inserted through the second via 105c. In some embodiments, the second intermediate member 106 is deformable and penetrable by the conductive pillar 103 during the disposing of the second chip 105. In some embodiments, the conductive pillar 103 is inserted into the second intermediate member 106 while the second intermediate member 106 is soft and has not been cured. In some embodiments, the second intermediate member 106 is cured after the disposing of the second chip 105. In some embodiments, the second conductive bump 105d is disposed over the first chip 102. In some embodiments, a semiconductor structure 100 with configuration similar to those described above or illustrated in FIG. 1 is formed.

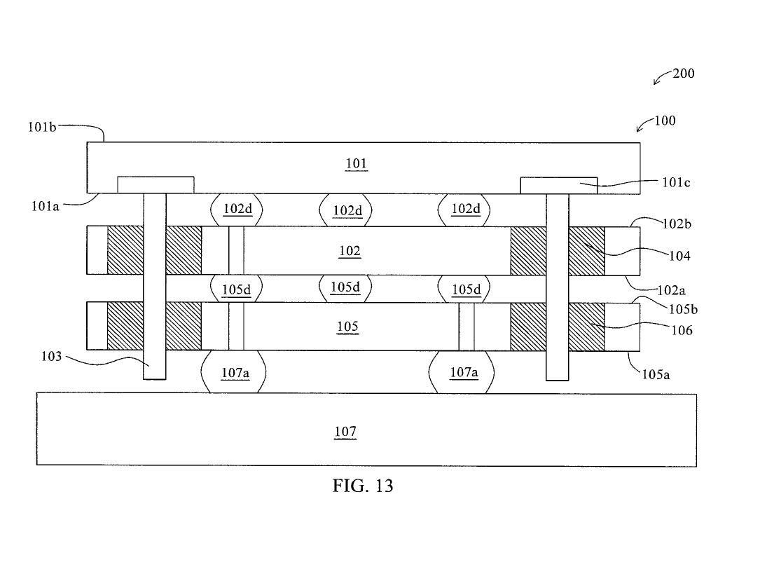

In some embodiments, the semiconductor structure 100 is flipped and then disposed over a circuit board 107 as shown in FIG. 13. In some embodiments, the semiconductor structure 100 is bonded with the circuit board 107 by a connector 107a. In some embodiments, a semiconductor structure 200 with configuration similar to those described above or illustrated in FIG. 2 is formed.

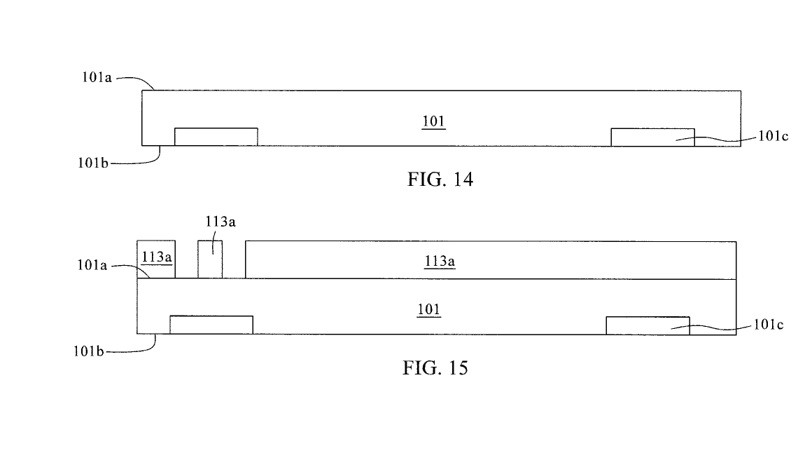

In some embodiments of the step 501, the substrate 101 is provided or received, and the conductive pad 101c is disposed within the substrate 101 or over the second surface 101b as shown in FIG. 14.

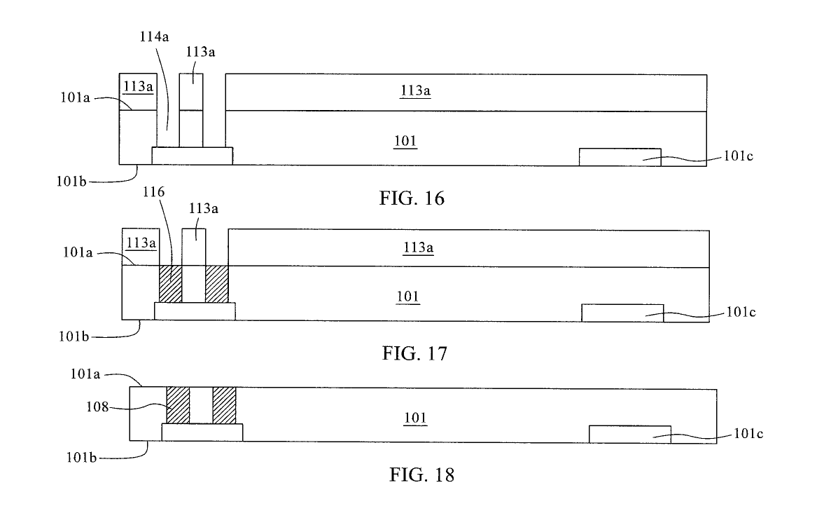

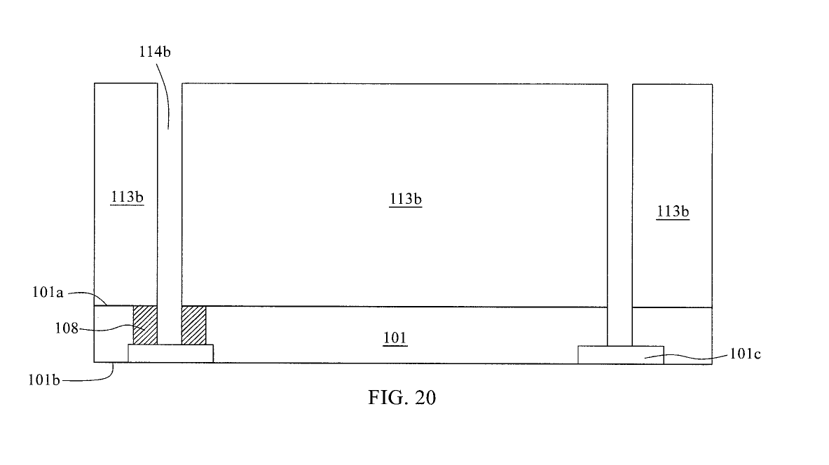

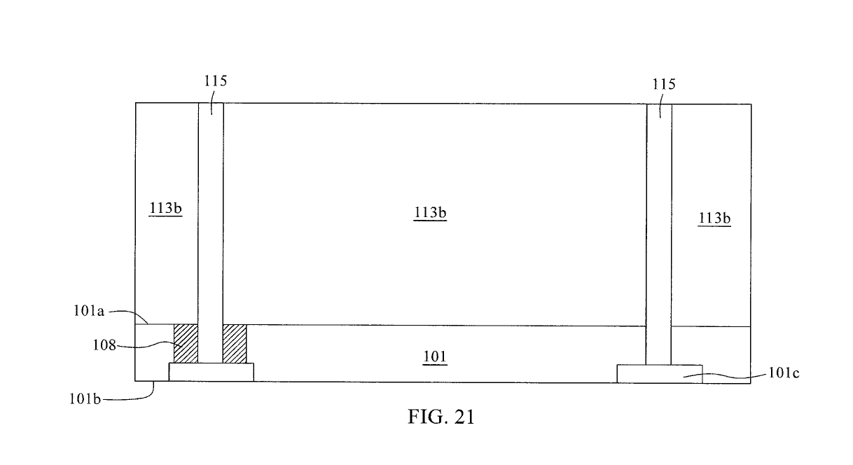

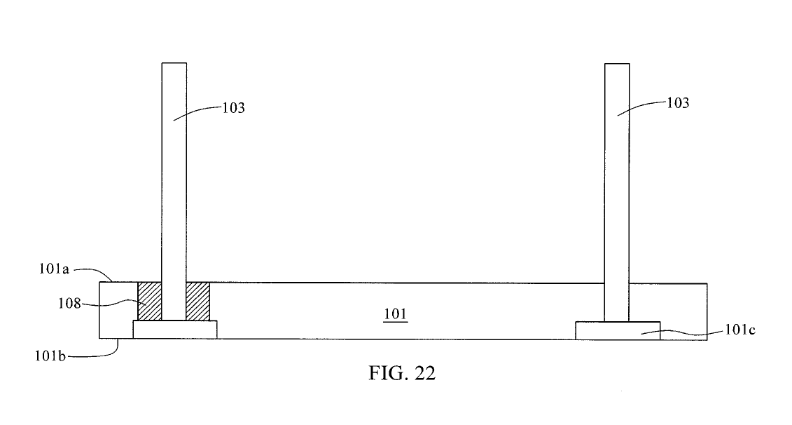

In some embodiments of the step 502, the conductive pillar 103 is formed as shown in FIGS. 15 to 22. In some embodiments, a third intermediate member 108 is formed before the formation of the conductive pillar 103 as shown in FIGS. 15 to 18. In some embodiments, the third intermediate member 108 is formed by disposing a first photoresist 113a over the substrate 101, removing a portion of the first photoresist 113a, removing a portion of the substrate 101 to form a first recess 114a, disposing an intermediate member material 116 into the first recess 114a, and removing the first photoresist 113a from the substrate 101.

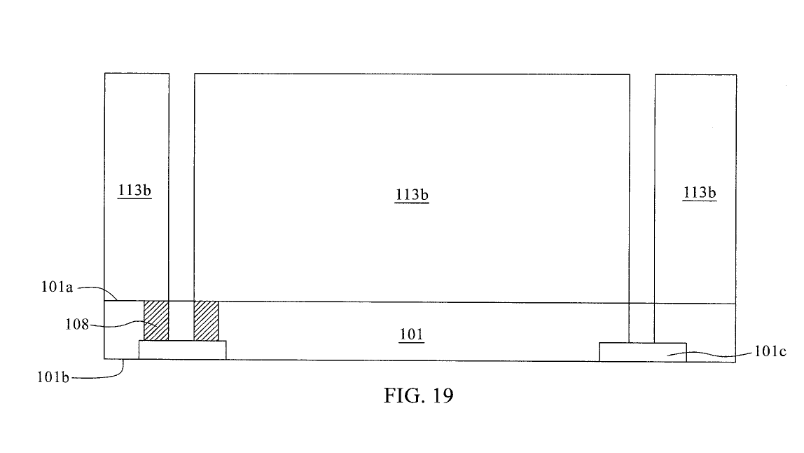

In some embodiments, the conductive pillar 103 is formed over the conductive pad 101c as shown in FIGS. 19 to 22. In some embodiments, the conductive pillar 103 is formed by disposing a second photoresist 113b over the substrate 101, removing a portion of the second photoresist 113b, removing a portion of the substrate 101 to expose a portion of the conductive pad 101c and form a second recess 114b, disposing the conductive material 115 into the second recess 114b, and removing the second photoresist 113b from the substrate 101.

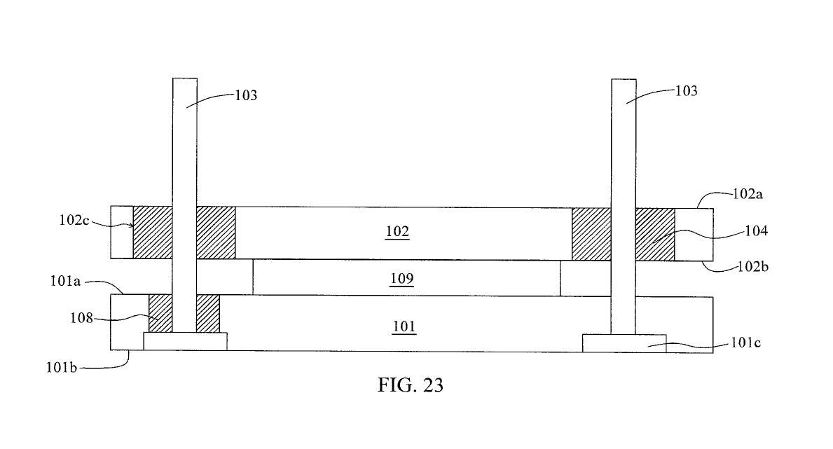

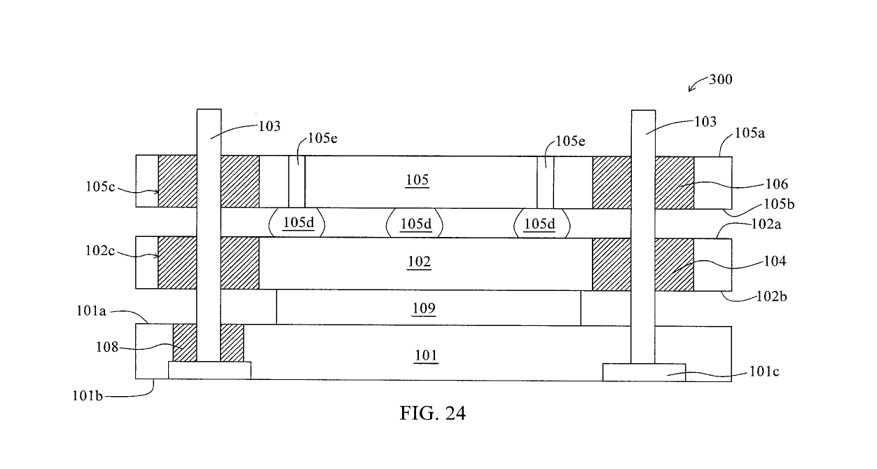

In some embodiments of the step 504, the first chip 102 is disposed over the substrate 101 as shown in FIG. 23. In some embodiments, the first chip 102 is disposed over the substrate 101 in a manner similar to those described above or illustrated in FIG. 11. In some embodiments, the first chip 102 is attached to the substrate 101 by an adhesive 109. In some embodiments, the second chip 105 is disposed over the first chip 102 as shown in FIG. 24. In some embodiments, the second chip 105 is disposed over the first chip 102 in a manner similar to those described above or illustrated in FIG. 12. In some embodiments, a semiconductor structure 300 with configuration similar to those described above or illustrated in FIG. 3 is formed.

In the present disclosure, a semiconductor structure is disclosed. The semiconductor structure comprises a conductive pillar protruding from the substrate, and a chip is disposed over the substrate and includes a via extending through the chip. The conductive pillar extends from the substrate through the chip and is partially disposed within the via. As such, the chip can be accurately disposed. The chip is aligned with the substrate by the conductive pillar. As a result, misalignment of the chip can be minimized or prevented. Further, the conductive pillar can absorb or relieve stress that develops around a conductive bump disposed between the chip and the substrate.

A semiconductor structure includes a substrate including a conductive pillar protruded from the substrate; and a first chip disposed over the substrate and including a first via extended through the first chip, wherein the conductive pillar is extended from the substrate through the first chip and is partially disposed within the first via.

A method of manufacturing a semiconductor structure includes providing a substrate; forming a conductive pillar disposed over and protruded from the substrate; providing a first chip including a first via extended through the first chip; and disposing the first chip over the substrate to insert the conductive pillar through the first via.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

1. A semiconductor structure, comprising:
a substrate including a conductive pillar protruded from the substrate, the conductive pillar being made of conductive material;
a first chip disposed over the substrate and including a first via extended through the first chip; and
a first intermediate member disposed within the first via and surrounding a portion of the conductive pillar,
wherein a melting point of the conductive pillar is substantially higher than a melting point of the first intermediate member, and
wherein the conductive pillar is extended from the substrate through the first chip and is partially disposed within the first via.

2. The semiconductor structure of claim 1, wherein the substrate is vertically aligned with the first chip by the conductive pillar.

3. (canceled)

4. (canceled)

5. The semiconductor structure of claim 1, wherein the first intermediate member includes tin or solder.

6. The semiconductor structure of claim 1, wherein the conductive pillar is disposed over or partially protruded into the substrate.

7. The semiconductor structure of claim 1, wherein the substrate includes a conductive pad disposed over a surface of the substrate or disposed within the substrate, and the conductive pillar is electrically coupled with the conductive pad.

8. The semiconductor structure of claim 1, wherein the conductive pillar includes copper, silver or gold.

9. The semiconductor structure of claim 1, further comprising a second chip disposed over the first chip and the substrate and including a second via extended through the second chip, wherein the conductive pillar is extended through the second chip and is partially disposed within the second via.

10. The semiconductor structure of claim 9, wherein the conductive pillar is partially protruded from the second chip.

11. The semiconductor structure of claim 9, wherein the second chip includes a second intermediate member disposed within the second via and surrounding a portion of the conductive pillar.

12. The semiconductor structure of claim 1, further comprising an adhesive disposed between the substrate and the first chip.

13. The semiconductor structure of claim 1, further comprising a first conductive bump disposed between the substrate and the first chip and electrically connecting the substrate with the first chip.

14. The semiconductor structure of claim 9, further comprising a second conductive bump disposed between the first chip and the second chip and electrically connecting the first chip with the second chip.

15. A method of manufacturing a semiconductor structure, comprising:
providing a substrate;
forming a conductive pillar disposed over and protruded from the substrate, the conductive pillar being made of conductive material;
providing a first chip including a first via extended through the first chip;
disposing the first chip over the substrate to insert the conductive pillar through the first via,
wherein the first chip includes a first intermediate member disposed within the first via, and
wherein a melting point of the conductive pillar is substantially higher than a melting point of the first intermediate member.

16. The method of claim 15, wherein the conductive pillar is inserted into the first intermediate member during the disposing of the first chip.

17. The method of claim 15, wherein the first intermediate member is deformable and penetrable by the conductive pillar during the disposing of the first chip.

18. The method of claim 15, wherein the forming of the conductive pillar includes disposing a photoresist over the substrate, removing a portion of the photoresist to form a recess, disposing the conductive material into the recess, and removing the photoresist from the substrate.

19. The method of claim 18, wherein the conductive material is disposed by electroplating, or the portion of the photoresist is removed by etching.

20. The method of claim 15, further comprising:
providing a second chip including a second via extended through the second chip;
disposing the second chip over the first chip to insert the conductive pillar through the second via;
providing the second chip including a second intermediate member disposed within the second via; and
inserting the conductive pillar into the second intermediate member.

21. The semiconductor structure of claim 1, wherein the conductive pillar is partially protruded into the substrate.

22. The semiconductor structure of claim 9, further comprising a conductive post disposed in the second chip and connected to the second conductive bump.
